(19) United States
(12) Patent Application Publication
(10) Pub. No.: US 2026/0140564 A1
(43) Pub. Date: May 21, 2026

(54) POWER DOMAIN MANAGEMENT CIRCUIT AND SYSTEM ON CHIP

(71) Applicant: SHENZHEN MICROBT ELECTRONICS TECHNOLOGY CO., LTD., SHENZHEN, GUANGDONG (CN)

(72) Inventors: Chaoxian ZHOU, SHENZHEN, GUANGDONG (CN); Hongxing WAN, SHENZHEN, GUANGDONG (CN); Zuoxing YANG, SHENZHEN, GUANGDONG (CN)

(73) Assignee: SHENZHEN MICROBT ELECTRONICS TECHNOLOGY CO., LTD., SHENZHEN, GUANGDONG (CN)

(21) Appl. No.: 19/481,574

(22) PCT Filed: May 14, 2025
(86) PCT No.: PCT/CN2025/094772

§ 371 Date: Nov. 5, 2025

(30) Foreign Application Priority Data
Sep. 29, 2024 (CN) 202411380168.X

(51) Int. Cl. G06F 1/3287; G06F 1/24; H03K 19/173

(52) U.S. Cl. CPC G06F 1/3287; G06F 1/24; H03K 19/1737

(57) ABSTRACT

The present disclosure relates to a power domain management circuit and a system on chip. The power domain management circuit includes: an enable unit, configured to generate an enable signal with a first preset level in a case of receiving an isolation set signal, or to generate an enable signal with a second preset level in a case of receiving a reset indication signal; and a clamping unit, electrically connected to the enable unit, and configured to clamp an initial signal transmitted from a first power domain to a second power domain to generate a target signal with a third preset level in a case of receiving the enable signal with the first preset level, or to skip clamping the initial signal to generate a target signal with a level that varies with a level of the initial signal in a case of receiving the enable signal with the second preset level.

### CROSS-REFERENCE TO RELATED APPLICATIONS

The present application is based on and claims priority to Chinese Patent Application No. 202411380168. X, filed on Sep. 29, 2024, the disclosure of which is incorporated herein by reference in its entirety.

### TECHNICAL FIELD

The present disclosure relates to the technical field of electronic circuit, and more particularly, to a power domain management circuit and a system on chip.

### BACKGROUND

In an integrated circuit chip, to reduce the operating power consumption, a plurality of power domains may be designed as required, and a corresponding power domain may be controlled to be turned on and off. In addition, there may be signal interaction between different power domains. To ensure the normal operation of each power domain, it is necessary to manage the signal isolation or interaction state between the power domains.

### SUMMARY

One of the objectives of the present disclosure is to provide a power domain management circuit and a system on chip.

According to a first aspect of the present disclosure, there is provided a power domain management circuit, including:
an enable unit, configured to generate an enable signal with a first preset level in a case of receiving an isolation set signal, or to generate an enable signal with a second preset level in a case of receiving a reset indication signal, wherein the second preset level is different from the first preset level; and
a clamping unit, electrically connected to the enable unit and configured to clamp an initial signal transmitted from a first power domain to a second power domain to generate a target signal with a third preset level in a case of receiving the enable signal with the first preset level, or to skip clamping the initial signal to generate a target signal with a level that varies with a level of the initial signal in a case of receiving the enable signal with the second preset level, wherein the third preset level is same as or different from the first preset level.

In some embodiments, the isolation set signal is configured to be generated before the first power domain is powered down relative to the second power domain; or
the reset indication signal is configured to be generated after the first power domain is powered up relative to the second power domain and is in a stable power-up state.

In some embodiments, the reset indication signal is configured to reset at least a portion of circuit components in the first power domain after the first power domain is powered up relative to the second power domain.

In some embodiments, the enable unit includes a first register.

In some embodiments, a reset trigger terminal of the first register is configured to receive the reset indication signal, and an output terminal of the first register is configured to output the enable signal.

In some embodiments, the clamping unit includes a first clamping unit, and the initial signal includes a clock signal; and
a first input terminal of the first clamping unit is configured to receive the enable signal, a second input terminal of the first clamping unit is configured to receive the clock signal, and an output terminal of the first clamping unit is electrically connected to a clock trigger terminal of the first register.

In some embodiments, the clamping unit includes a second clamping unit, the initial signal includes an isolation setup signal, and the target signal includes the isolation set signal generated according to the enable signal and the isolation setup signal; and
a first input terminal of the second clamping unit is configured to receive the enable signal, a second input terminal of the second clamping unit is configured to receive the isolation setup signal, and an output terminal of the second clamping unit is electrically connected to an input terminal of the first register to transmit the isolation set signal to the first register.

In some embodiments, the power domain management circuit further includes:
a state control unit, electrically connected to the enable unit and configured to generate, according to the enable signal, a state control signal to be transmitted to the first power domain.

In some embodiments, the state control unit includes a first multiplexer, a selection control terminal of the first multiplexer is electrically connected to an output terminal of the enable unit, each of a plurality of input terminals of the first multiplexer is respectively configured to receive a corresponding state control signal, and an output terminal of the first multiplexer is configured to output a state control signal selected according to the enable signal.

In some embodiments, the state control unit includes a second register, the clamping unit includes a first clamping unit and a third clamping unit, the initial signal includes an input control signal, and the target signal includes a state indication signal generated according to the enable signal and the input control signal;
a reset trigger terminal of the second register is configured to receive the reset indication signal;
a first input terminal of the first clamping unit is configured to receive the enable signal, a second input terminal of the first clamping unit is configured to receive a clock signal, and an output terminal of the first clamping unit is electrically connected to a clock trigger terminal of the second register; or
a first input terminal of the third clamping unit is configured to receive the enable signal, a second input terminal of the third clamping unit is configured to receive the input control signal, and an output terminal of the third clamping unit is electrically connected to an input terminal of the second register to transmit the state indication signal to the second register.

In some embodiments, the second register is configured to generate a state control signal corresponding to the input control signal in a case of receiving the state indication signal, or to generate a state control signal corresponding to a normal working state in a case of receiving the reset indication signal.

In some embodiments, the state control unit further includes a delay module, an output terminal of the second register is electrically connected to an input terminal of the delay module, and the delay module is configured to delay the state indication signal.

In some embodiments, the delay module includes a second multiplexer, a selection control terminal of the second multiplexer is electrically connected to an output terminal of the enable unit, one input terminal of the second multiplexer is electrically connected to an output terminal of the second register, and an output terminal of the second multiplexer is configured to output a state control signal selected according to the enable signal.

In some embodiments, another input terminal of the second multiplexer is configured to receive a state control signal corresponding to a normal working state.

In some embodiments, the state control signal includes at least one of:
a state control signal configured to maintain power supply to a storage array of a static random access memory in the first power domain;
a state control signal configured to maintain power supply to an input/output of an input/output unit in the first power domain;
a state control signal configured to keep an analog circuit component in the first power domain in a shutdown state or a standby state; or
a state control signal configured to keep the first power domain in a normal working state.

In some embodiments, the power domain management circuit further includes:
a power-up identification unit, configured to identify whether current power-up of the first power domain is initial power-up or power-up after sleep.

In some embodiments, the power-up identification unit includes a latch, and the latch is configured to receive a power-up indication signal from a power supply, and to generate, according to the reset indication signal and the power-up indication signal, a power-up identification signal for identifying whether the current power-up of the first power domain is the initial power-up or the power-up after sleep.

In some embodiments, the clamping unit includes:
an AND gate circuit, wherein a first input terminal of the AND gate circuit is configured to receive the enable signal, a second input terminal of the AND gate circuit is configured to receive the initial signal, and an output terminal of the AND gate circuit is configured to output the target signal, wherein the first preset level is a low level, and the second preset level is a high level; or
an OR gate circuit, wherein a first input terminal of the OR gate circuit is configured to receive the enable signal, a second input terminal of the OR gate circuit is configured to receive the initial signal, and an output terminal of the OR gate circuit is configured to output the target signal, wherein the first preset level is the high level, and the second preset level is the low level.

In some embodiments, the power domain management circuit is arranged in the second power domain.

According to a second aspect of the present disclosure, there is provided a system on chip with a first power domain and a second power domain, and the system on chip includes the power domain management circuit as described above.

In some embodiments, the system on chip further includes:
a power supply, configured to supply power to the first power domain and the second power domain.

Through the detailed description of exemplary embodiments of the present disclosure, with reference to the following accompanying drawings, other features and advantages of the present disclosure will become clearer.

### BRIEF DESCRIPTION OF THE DRAWINGS

The accompanying drawings that constitute a part of the specification illustrate embodiments of the present disclosure, and are used to explain the principle of the present disclosure together with the specification.

With reference to the accompanying drawings, according to the following detailed description, the disclosure will be understood more clearly, wherein:

FIG. 1 shows a block diagram of a system on chip according to an exemplary embodiment of the present disclosure;

FIG. 2 shows a circuit schematic diagram of a power domain management circuit according to a specific embodiment of the present disclosure;

FIG. 3 shows a timing relationship diagram of an isolation setup signal, a power supply signal of a power supply to a first power domain, and a reset indication signal in a process in which the power domain management circuit of FIG. 2 is used for powering down and powering up the first power domain;

FIG. 4 shows a circuit schematic diagram of a state control unit in a power domain management circuit according to a specific embodiment of the present disclosure;

FIG. 5 shows a circuit schematic diagram of a power domain management circuit according to another specific embodiment of the present disclosure;

FIG. 6 shows a circuit schematic diagram of a state control unit and an associated clamping unit in a power domain management circuit according to a specific embodiment of the present disclosure;

FIG. 7 shows a circuit schematic diagram of a state control unit and an associated clamping unit in a power domain management circuit according to another specific embodiment of the present disclosure; and

FIG. 8 shows a timing relationship diagram of a power-up indication signal, a reset indication signal, and a power-up identification signal in a power domain management circuit according to a specific embodiment of the present disclosure.

It is to be noted that in the following implementations illustrated, sometimes a same reference numeral is used in different accompanying drawings to represent a same part or a part with a same function, and repeated illustration thereof is omitted. In the specification, similar numbers and letters are used to represent similar items. Therefore, once an item is defined in an accompanying drawing, the item in subsequent accompanying drawings will not be further discussed.

For ease of understanding, the position, size, range and the like of each structure shown in the accompanying drawings may not indicate the actual position, size, range and the like. Therefore, the disclosed invention is not limited to the position, size, range and the like disclosed in the accompanying drawings. Moreover, the accompanying drawings are not necessarily drawn to scale, and some features may be exaggerated to show details of specific components.

### DETAILED DESCRIPTION

Various exemplary embodiments of the present disclosure are described in detail with reference to the accompanying drawings in the following. It should be noted that unless illustrated in detail otherwise, the relative deployment of the components and steps, the numerical expressions and the values stated in these embodiments do not limit the scope of the present disclosure.

In fact, the following description of at least one exemplary embodiment is merely illustrative, and is not as any limitation to the present disclosure and to application or use thereof. That is, the structure and the method herein are given in an exemplary manner to illustrate different embodiments of the structure and the method in the present disclosure. However, one skilled in the art will understand that they merely illustrate exemplary, rather than exhaustive manner in which the present disclosure may be implemented. Moreover, the accompanying drawings are not necessarily drawn to scale, and some features may be exaggerated to show the details of specific components.

In addition, technologies, methods, and apparatuses known to a person of ordinary skill in the art may not be discussed in detail, but in proper circumstances, the technologies, methods, and apparatuses shall be regarded as a part of the specification.

In all examples shown and discussed herein, any specific value should be interpreted only as an example but not as a limitation. Therefore, other examples of the exemplary embodiments may have different values.

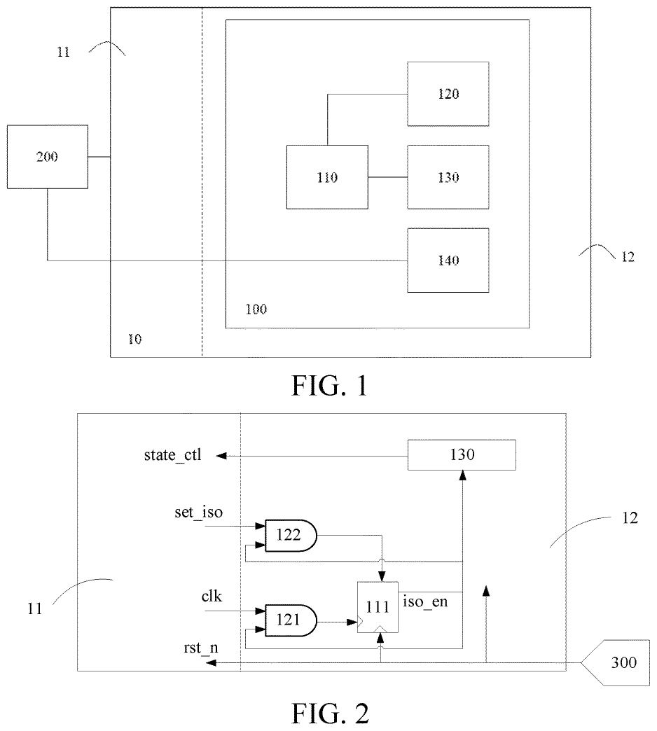

In an integrated circuit chip or a system on chip (SOC), a plurality of power domains may be arranged, wherein turn-on or turn-off (power-up or power-down) of different power domains may be controlled independently. In this way, it is possible to dynamically switch a corresponding power domain according to a specific working scenario, thereby helping to save power consumption of a circuit or a chip. In a circuitry, power supply may be implemented by a power supply. In some examples, as shown in FIG. 1, the power supply 200 such as a power supply chip (PMIC) may be arranged independent of the SOC 10. Alternatively, in some other examples, the power supply may be arranged inside the SOC.

The SOC may have at least two power domains. In this specification, as shown in FIG. 1, the technical solution of the present disclosure is set forth in detail by using an example in which the SOC 10 has a first power domain 11 and a second power domain 12. However, it may be understood that, the SOC may have more power domains as required, which is not limited herein. In this specification, it is assumed that the first power domain 11 is a power-down domain relative to the second power domain 12, and the second power domain 12 is a power-up domain relative to the first power domain 11. In other words, in a case that the first power domain 11 is in the power-up state, the second power domain 12 is also in the power-up state, and in a case that the second power domain 12 is in the power-up state, the first power domain 11 may be in the power-up state for some time periods, and may be in the power-down state for some other time periods. Then, in a case that the power supply states of the first power domain 11 and the second power domain 12 are inconsistent, the signal interaction between the two power domains usually needs to be isolated, so as to prevent, for example, an uncertain signal from the power-down domain from being transmitted to the power-up domain and affecting the normal operation of the power-up domain. While in a case that both the first power domain 11 and the second power domain 12 are in the power-up states, the signal isolation therebetween usually needs to be eliminated, so that the necessary signal interaction may be performed between the different power domains to enable the SOC to operate normally.

In an exemplary embodiment, the signal isolation or interaction between the power domains may be controlled by the arrangement of a power domain management circuit (PMU). For example, as shown in FIG. 1, the SOC 10 may include the power domain management circuit 100. Alternatively, in some other embodiments, the power domain management circuit may be arranged independent of the SOC, which is not limited herein. In addition, in some embodiments, the power domain management circuit 100 may be arranged in the second power domain 12, so as to manage the signal isolation or interaction state between the different power domains as required at any time. For example, in a state where the first power domain 11 is powered down, the power domain management circuit 100 arranged in the second power domain 12 may still operate normally. In an exemplary embodiment, as shown in FIG. 1, the power domain management circuit 100 may include an enable unit 110 and a clamping unit 120.

The enable unit 110 may be configured to generate an enable signal with a first preset level in a case of receiving an isolation set signal. Alternatively, the enable unit 110 may be configured to generate an enable signal with a second preset level in a case of receiving a reset indication signal. Herein, the second preset level is different from the first preset level, so as to distinguish between the different working states. For example, in a case that the first preset level is a low level (indicated by 0), the second preset level may be a high level (indicated by 1). While in a case that the first preset level is the high level, the second preset level may be the low level. The isolation set signal may be used for controlling the setting of the enable signal, as will be further described in detail below.

The clamping unit 120 may be electrically connected to the enable unit 110, so as to determine, according to the enable signal from the enable unit 110, whether to clamp a signal transmitted from the first power domain 11 to the second power domain 12, to implement the signal isolation or interaction between the first power domain 11 and the second power domain 12. In particular, the clamping unit 120 may be configured to, in a case of receiving the enable signal with the first preset level, or in response to the isolation set signal, clamp an initial signal transmitted from the first power domain 11 to the second power domain 12 to generate a target signal with a third preset level. Herein, the third preset level may be same as or different from the first preset level, that is, a specific form of the third preset level is not limited. The third preset level may be the high level, the low level, or a preset combination of the high level and the low level (such as 101, 110 and the like), provided that the third preset level is independent of a level variation of the initial signal and is known in advance or fixed, thereby implementing the signal isolation. Alternatively, the clamping unit 120 may be configured to, in a case of receiving the enable signal with the second preset level, or in response to the reset indication signal, skip clamping the initial signal to generate a target signal with a level that varies with a level of the initial signal. For example, in a specific example, the target signal may be same as the initial signal. That is, in response to the reset indication signal, the clamping unit 120 may directly use the initial signal as the target signal to be transmitted to the second power domain 12, thereby implementing the signal interaction between the first power domain 11 and the second power domain 12. Alternatively, according to a specific application requirement, the clamping unit 120 may perform some processing on the initial signal, such as inverting the initial signal and the like, to generate the target signal to be transmitted to the second power domain 12, wherein the target signal has the level varying with the level of the initial signal but is different from the initial signal. It may be understood according to the description that, in response to the reset indication signal, although the target signal is not necessarily completely the same as the initial signal, a change in the level of the target signal is usually associated with that of the initial signal, which is equivalent to implementing the signal interaction between the first power domain 11 and the second power domain 12.

In some embodiments, the isolation set signal may be configured to be generated before the first power domain 11 is powered down relative to the second power domain 12, so that the signal isolation between the first power domain 11 and the second power domain 12 is completed before the first power domain 11 is powered down, to prevent an uncertain signal in the first power domain 11 from being transmitted to the second power domain 12, thereby ensuring the normal operation of the SOC 10. In addition, the reset indication signal may be configured to be generated after the first power domain 11 is powered up relative to the second power domain 12. Further, the reset indication signal may be configured to be generated after the first power domain 11 is powered up and has reached a stable power-up state, to restore the signal interaction between the first power domain 11 and the second power domain 12, thereby ensuring the normal operation of the SOC 10.

In some embodiments, for example, in a case that the first power domain 11 includes a digital circuit component, the reset indication signal may further be configured to reset at least a portion of circuit components (for example, the digital circuit component and/or an analog circuit component that needs to be reset, etc.) in the first power domain 11 after the first power domain 11 is powered up relative to the second power domain 12, to eliminate a negative impact of an uncertain or incorrect signal state on the SOC 10.

In some embodiments, the enable unit 110 may be implemented by using a sequential logic circuit, to generate the expected enable signal according to the isolation set signal or the reset indication signal. For example, the enable unit 110 may include a register, a latch, a combination thereof, or the like. In another aspect, the clamping unit 120 may be implemented by using a combinational logic circuit, to generate the expected target signal according to the enable signal and the initial signal. For example, the clamping unit 120 may include an AND gate circuit, an OR gate circuit, a NOT gate circuit, a combination thereof, or the like.

In a specific embodiment, as shown in FIG. 2, the enable unit 110 may include a first register 111. The first register 111 may have a reset trigger terminal, a clock trigger terminal, an input terminal, and an output terminal.

In addition, the clamping unit 120 may be formed by an AND gate circuit. A first input terminal of the AND gate circuit may be configured to receive the enable signal, a second input terminal of the AND gate circuit may be configured to receive the initial signal, and an output terminal of the AND gate circuit may be configured to output the target signal. That is, the target signal may be an AND operation result of the enable signal and the initial signal. Correspondingly, to effectively control the signal isolation or interaction between the power domains, the first preset level may be the low level, and the second preset level may be the high level. In this way, by means of the AND gate circuit, in response to the isolation set signal, the initial signal may be clamped to the low level under the action of the enable signal, thereby implementing the signal isolation between the power domains. While in response to the reset indication signal, the initial signal may not be clamped by the enable signal in the high-level state, but may be output from the output terminal of the AND gate circuit as it is or substantially as it is, thereby implementing the signal interaction between the power domains.

In addition, the power domain management circuit 100 may include one or more clamping units 120 as required. In the specific embodiment shown in FIG. 2, the clamping unit 120 of the power domain management circuit 100 may include a first clamping unit 121 and a second clamping unit 122. An initial signal input to the first clamping unit 121 may include a clock signal (clk), and an initial signal input to the second clamping unit 122 may include an isolation setup signal (set_iso).

In the specific embodiment shown in FIG. 2, the reset trigger terminal of the first register 111 may be configured to receive the reset indication signal (rst_n), and the output terminal of the first register 111 may be configured to output the enable signal (iso_en). The reset indication signal (rst_n) may be sourced from a reset pin 300. In some embodiments, the reset pin 300 may be integrated in the second power domain 12. In this way, even in a case that the first power domain 11 is powered down, the reset indication signal can still be generated, so as to restore the signal interaction between the power domains.

As shown in FIG. 2, a first input terminal of the first clamping unit 121 may be configured to receive the enable signal (iso_en), a second input terminal of the first clamping unit 121 may be configured to receive the clock signal (clk), and an output terminal of the first clamping unit 121 may be electrically connected to the clock trigger terminal of the first register 111. In this way, in a case that the first power domain 11 is in the power-up state, the clock signal (clk) may be transmitted from the first power domain 11 to the second power domain 12 via the first clamping unit 121, to provide a clock in the second power domain 12. While in a case that the first power domain 11 is in the power-down state, the clock signal (clk) is clamped to the low level by the first clamping unit 121, at this time., the second power domain 12 may be in a clock-free state, which helps to reduce the power consumption of the SOC 10.

As shown in FIG. 2, a first input terminal of the second clamping unit 122 may be configured to receive the enable signal (iso_en), a second input terminal of the second clamping unit 122 may be configured to receive the isolation setup signal (iso_set), and an output terminal of the second clamping unit 122 may be electrically connected to the input terminal of the first register 111 to enable the isolation set signal to be transmitted to the first register 111. The isolation set signal as the target signal may be generated according to the enable signal (iso_en) and the isolation setup signal (set_iso), for example, may be an AND operation result of the enable signal and the isolation setup signal.

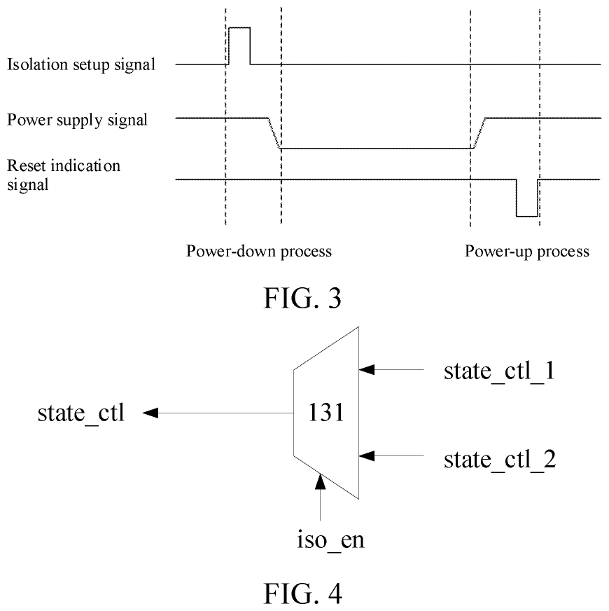

As shown in FIGS. 2 and 3, in a process of powering down the first power domain 11, the isolation setup signal (set_iso) with a high-level pulse may be first generated in the first power domain 11. For example, the isolation setup signal may be generated under control of a circuit component, such as a central processing unit (CPU) or the like, arranged in the first power domain 11. At this time, because both the first power domain 11 and the second power domain 12 are in the power-up state, the enable signal (iso_en) may be in the high-level state. Correspondingly, the isolation setup signal (set_iso) is not clamped by the second clamping unit 122, but may be transmitted from the first power domain 11 to the second power domain 12 via the second clamping unit 122, so that the input terminal of the first register 111 can receive the high-level pulse. In addition, the clock signal (clk) is not clamped by the first clamping unit 121 either, but may be transmitted from the first power domain 11 to the second power domain 12 via the first clamping unit 121, so that the clock trigger terminal of the first register 111 can receive the clock signal. Further, under the triggering action of a rising edge or a falling edge of the clock signal, based on the high-level pulse received at the input terminal of the first register 111, the enable signal (iso_en) output from the output terminal of the first register 111 may be converted from the high-level state to the low-level state. Then, the enable signal (iso_en) in the low-level state may enable each clamping unit 120 to clamp the initial signal from the first power domain 11 to the target signal with the third preset level, thereby implementing the signal isolation between the first power domain 11 and the second power domain 12. After the signal isolation between the power domains has been completed, the power supply 200 may stop supplying power to the first power domain 11 (that is, a power supply signal of the power supply to the first power domain may be converted to the low-level state), thereby completing power-down of the first power domain 11. As described above, in some embodiments, no local clock or clock signal may be arranged in the second power domain 12. In this way, during a period in which the first power domain 11 is in the power-down state relative to the second power domain 12, the logic associated with the clock or the clock signal in the second power domain 12 is not inverted either, thereby helping to reduce the power consumption of the second power domain 12 or the entire SOC 10. In addition, to restore the power supply to the first power domain 11 in a proper case, the clock or the clock signal may be set in the power supply 200 to time the power-down state of the first power domain 11, or another circuit component may be set to monitor a proper power-up opportunity, and to generate a corresponding signal to indicate the power-up of the first power domain 11.

As shown in FIGS. 2 and 3, in a process of powering up the first power domain 11, the power supply 200 may first supply power to the first power domain 11, and wait until the power supply state is stable (that is, the power supply signal of the power supply to the first power domain is converted to the high-level state and tends to be stable). At this time, the enable signal (iso_en) may be in the low-level state. Therefore, the first power domain 11 and the second power domain 12 are still in the signal isolation state. Then, for example, the reset indication signal (rst_n) with the low-level pulse may be generated by the reset pin 300, to trigger the enable signal (iso_en) output from the output terminal of the first register 111 to be reset from the low-level state to the high-level state. For example, the signal at the reset pin 300 may be first pulled down and then pulled up through the power supply chip, so as to generate the reset indication signal (rst_n) with the low-level pulse. Then, the enable signal (iso_en) in the high-level state may enable each clamping unit 120 to skip clamping a corresponding initial signal from the first power domain 11, that is, each clamping unit 120 may output a corresponding target signal with a level that varies with the level of the corresponding initial signal, thereby implementing the signal interaction between the first power domain 11 and the second power domain 12. In addition, as described above, the reset indication signal (rst_n) with the low-level pulse may also be transmitted to at least a portion of circuit components (for example, the digital circuit component and/or the analog circuit component that needs to be reset, etc.) in the first power domain 11, so that these circuit components are reset, thereby ensuring the normal operation thereof.

It may be understood that, in some other embodiments, the enable unit 110 and the clamping unit 120 may alternatively be set in another manner. In addition, an effective level or an effective edge of one or more of the signals described above such as the isolation set signal, the reset indication signal, the enable signal, the clock signal, and the isolation setup signal may also change, which is not limited herein.

For example, in some other embodiments, the clamping unit 120 may be formed by an OR gate circuit. A first input terminal of the OR gate circuit may be configured to receive the enable signal, a second input terminal of the OR gate circuit may be configured to receive the initial signal, and an output terminal of the OR gate circuit may be configured to output the target signal. That is, the target signal may be an OR operation result of the enable signal and the initial signal. Correspondingly, to effectively control the signal isolation or interaction between the power domains, the first preset level may be the high level, and the second preset level may be the low level. In this way, by means of the OR gate circuit, in response to the isolation set signal, the initial signal may be clamped to the high level under the action of the enable signal, thereby implementing the isolation between the power domains. While in response to the reset indication signal, the initial signal may not be clamped by the enable signal in the low-level state, but may be output from the output terminal of the OR gate circuit, thereby implementing the signal interaction between the power domains.

In addition, in some embodiments, the clamping unit 120 may alternatively be formed by a combination of two or more of various types of circuits such as an AND gate circuit, an OR gate circuit, a NOT gate circuit, and the like, as required, which is not limited herein. For example, the clamping unit 120 may be formed by an AND gate circuit and a NOT gate circuit connected to an output terminal of the AND gate circuit. In this way, compared with the clamping unit 120 shown in FIG. 2, the target signal may be inverted under the action of the NOT gate circuit, to meet a specific application requirement.

In addition, the enable unit 110 may alternatively be triggered or reset in another manner or by a signal in another form (for example, a signal with a different effective level or edge), to generate a corresponding enable signal, which is not limited herein either.

Further, in some embodiments, considering that at least a portion of circuit components in the SOC 10 are usually in different working states when the first power domain 11 is respectively in the power-up state and the power-down state, in order to control these working states, as shown in FIGS. 1, 2, and 4 to 7, the power domain management circuit 100 may further include a state control unit 130. The state control unit 130 may be electrically connected to the enable unit 110. The state control unit 130 may be configured to generate, according to the enable signal, a state control signal (state_ctl) to be transmitted to the first power domain 11, to set the working state (for example, a normal working state, a standby state, a shutdown state, or the like) of the related circuit component in the first power domain 11. It may be understood that the state control unit 130 may be set in multiple manners as required, which is not limited herein.

In a specific embodiment, as shown in FIGS. 2 and 4, the state control unit 130 may include a first multiplexer (MUX) 131. A selection control terminal of the first multiplexer 131 may be electrically connected to the output terminal of the enable unit 110, each of a plurality of input terminals of the first multiplexer 131 may be respectively configured to receive a corresponding state control signal, and an output terminal of the first multiplexer 131 may be configured to output a state control signal (state_ctl) selected according to the enable signal. For example, in a specific embodiment of FIG. 4, one input terminal of the first multiplexer 131 may be configured to receive a first state control signal (state_ctl_1) corresponding to the normal working state, and another input terminal may be configured to receive a second state control signal (state_ctl_2) corresponding to the standby state or the shutdown state. In this way, in a case that the selection control terminal of the first multiplexer 131 receives the enable signal at the first preset level, the output terminal of the first multiplexer 131 may select to output the second state control signal, to indicate a corresponding circuit component connected to the output terminal of the first multiplexer 131 in the first power domain 11 to work in the standby state or in the shutdown state, that is, in a case that the first power domain 11 is in the power-down state, the circuit component is in the standby state or in the shutdown state, to reduce the power consumption. While in a case that the selection control terminal of the first multiplexer 131 receives the enable signal at the second preset level, the output terminal of the first multiplexer 131 may select to output the first state control signal, to indicate a corresponding circuit component connected to the output terminal of the first multiplexer 131 in the first power domain 11 to work in the normal working state. It may be understood that the first multiplexer 131 may alternatively include more input terminals, so as to provide more types of state control signals to control an operating state of a related circuit component in the first power domain 11.

However, in the specific embodiment shown in FIG. 4, corresponding to a certain enable signal, a relevant state control signal thereof is fixed, and cannot be flexibly adjusted according to a user's requirement. For example, if corresponding to the enable signal at the first preset level, the second state control signal is used for indicating the shutdown state of the related circuit component, the related circuit component can only be in the shutdown state under the action of the second state control signal, but cannot be adjusted to be in the standby state, provided that the state control unit 130 receives the enable signal at the first preset level.

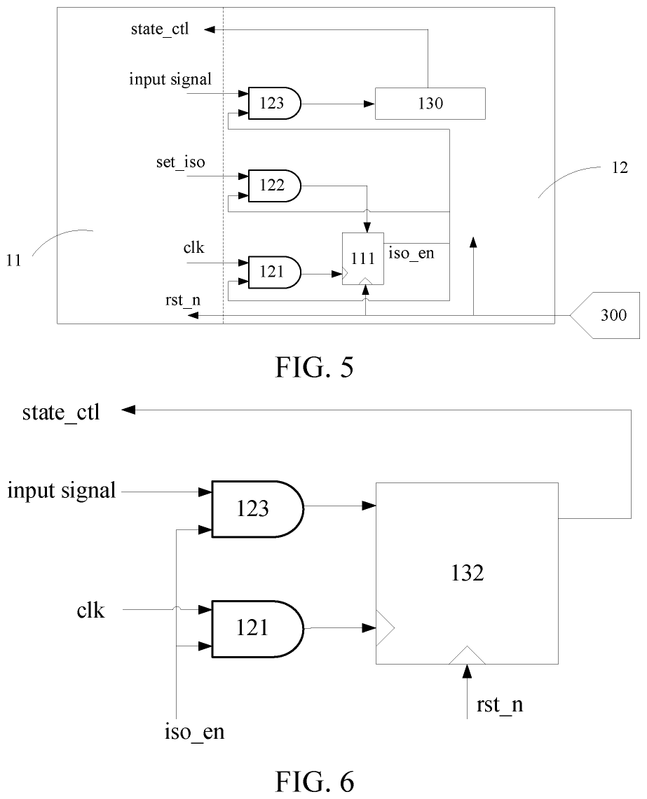

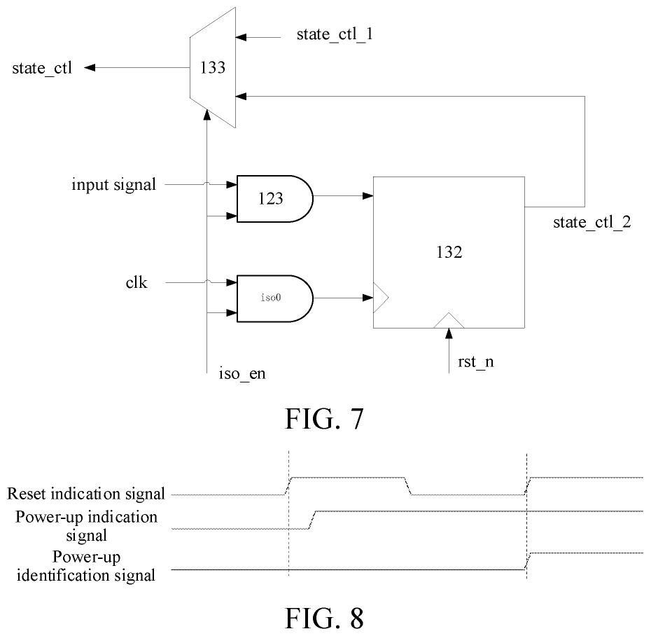

To resolve the foregoing problem, in another specific embodiment, as shown in FIGS. 5 to 7, the state control unit 130 may include a second register 132. In addition, the clamping unit 120 may include the first clamping unit 121 described above and a third clamping unit 123. It should be noted that, in a specific example, the first clamping unit 121 shown in FIGS. 6 and 7 is the first clamping unit 121 shown in FIG. 5, and the third clamping unit 123 shown in FIGS. 6 and 7 is the third clamping unit 123 shown in FIG. 5. Correspondingly, the initial signal may further include an input control signal (input_signal) to be transmitted to the third clamping unit 123, and the target signal may further include a state indication signal, which is generated according to the enable signal (iso_en) and the input control signal (input_signal). Under the combined action of the second register 132, the first clamping unit 121, and the third clamping unit 123, the configuration of the operating state or the working state of the related circuit component can be implemented.

Specifically, in the specific embodiment shown in FIG. 6, a reset trigger terminal of the second register 132 may be configured to receive the reset indication signal (rst_n). In addition, the first input terminal of the first clamping unit 121 may be configured to receive the enable signal (iso_en), the second input terminal of the first clamping unit 121 may be configured to receive the clock signal (clk), and the output terminal of the first clamping unit 121 may be electrically connected to a clock trigger terminal of the second register 132. A first input terminal of the third clamping unit 123 may be configured to receive the enable signal (iso_en), a second input terminal of the third clamping unit 123 may be configured to receive the input control signal (input_signal), and an output terminal of the third clamping unit 123 may be electrically connected to an input terminal of the second register 132 to transmit the state indication signal to the second register 132. In this way, an output terminal of the second register 132 may be configured to output the first state control signal used for indicating the normal working state in a case that the reset trigger terminal of the second register 132 receives the reset indication signal, to control the related circuit component in the first power domain 11 to operate in the normal working state. In a case that the clock trigger terminal of the second register 132 receives the target signal that is clamped to the third preset level, the output terminal of the second register 132 may output a state control signal corresponding to the state indication signal received by the input terminal of the second register. In this way, the working state of the related circuit component in the first power domain 11 in a case that the first power domain 11 is powered down may be configured by configuring the corresponding input control signal. For example, the working state may be the shutdown state in some cases, or may be the standby state in some other cases. It may be understood that, to better distinguish between various state control signals or working states, the state control signal may be formed by a plurality of bits. For example, the state control signal may be 0001 which corresponds to the standby state, be 0010 which corresponds to the shutdown state, and so on. Correspondingly, the third clamping unit 123 may clamp a corresponding bit of the input control signal to a preset level as required, to generate a corresponding state control signal, which is not limited herein.

In a specific embodiment, for example, a corresponding second register 132, clamping unit 120, and the like may be arranged for a static random access memory (SRAM) arranged in the first power domain 11, so as to configure the working state of the SRAM in a case that the first power domain 11 is in the powered-down state. Specifically, in a case that the first power domain 11 is powered down, the SRAM may be in the shutdown state, that is, the power supply of a storage array and the power supply of an interface of the SRAM may both be disconnected. At this time, content stored in the SRAM cannot be reserved. Alternatively, the SRAM may be in the retention state, that is, the power supply of the storage array of the SRAM is retained, while the power supply of the interface may be disconnected. At this time, the content stored in the SRAM may be reserved for subsequent usage. In addition, in a case that the first power domain 11 is powered up, the SRAM may be in the normal working state, that is, the power supply of the storage array and the power supply of the interface of the SRAM are both present. Then, when the state control unit 130 and the related clamping unit 120 shown in FIG. 6 are used to control the working state of the SRAM, in response that the second register 132 receives the enable signal at the first preset level, the output terminal of the second register 132 may generate the state control signal corresponding to the input control signal. In this way, different state control signals may be respectively generated by setting different input control signals, to control whether the SRAM works in the shutdown state or the retention state. While in response that the second register 132 receives the enable signal at the second preset level, the output terminal of the second register 132 may generate the first state control signal corresponding to the normal working state, to indicate the SRAM to work in the normal working state.

However, in the specific embodiment shown in FIG. 6, once the working state of the related circuit component in the power-down state is configured in the first power domain 11, the working state usually takes effect immediately, but at this time, the first power domain 11 may not enter the power-down state yet. However, in some cases, it is necessary to enable the related circuit component in the first power domain 11 to work in the configured working state only after the first power domain 11 enters the power-down state. For example, in a case that the state control signal is to be input to a circuit component such as a central processing unit (CPU) or the like arranged in the first power domain 11, it may be necessary to apply a certain delay to the state control signal, so that the circuit component enters the configured shutdown state, standby state, or the like only after the first power domain 11 is powered down, thereby ensuring the normal operation of the SOC 10. Therefore, as shown in FIG. 7, in another specific embodiment, the state control unit 130 may further include a delay module 133. The output terminal of the second register 132 may be electrically connected to an input terminal of the delay module 133, and the delay module 133 may be configured to delay the state indication signal. In the specific embodiment shown in FIG. 7, the delay module 133 may be formed by a second multiplexer (MUX). A selection control terminal of the second multiplexer may be electrically connected to the output terminal of the enable unit 110, an input terminal of the second multiplexer may be electrically connected to the output terminal of the second register 132, and an output terminal of the second multiplexer may be configured to output the state control signal selected according to the enable signal. In this way, because the state control signal is transmitted to the related circuit component in the first power domain 11 via the second multiplexer, a necessary delay may be introduced, to ensure the normal operation of the SOC 10.

In some specific examples, the first state control signal used for indicating the normal working state may alternatively be sourced from the second register 132. Alternatively, in some other specific examples, as shown in FIG. 7, another input terminal of the second multiplexer may be configured to receive the state control signal (the first state control signal (state_ctl_1)) corresponding to the normal working state. In this way, the second register 132 may be independently configured to set the state control signal in the power-down state of the first power domain 11.

A corresponding state control signal may be set according to a specific circuit component. For example, a main circuit component or logic of the SOC may be arranged in the first power domain 11, to save the power consumption to the greatest extent. Correspondingly, the static random access memory (SRAM), the input/output (IO) unit, and various analog circuit components (such as an analog IP component and the like) used for implementing specific functions may be arranged in the first power domain 11. In a specific example, the state control signal may include the state control signal configured to maintain the power supply of the storage array of the SRAM in the first power domain 11, so that in a case that the first power domain 11 is powered down, the information stored in the SRAM is still reserved, while another power supply to the SRAM can be cut off, thereby saving the power consumption. In another specific example, the state control signal may include the state control signal configured to maintain the power supply to the input/output of the IO unit in the first power domain 11, so that in a case that the first power domain 11 is powered down, the necessary input/output or signal interaction can still be implemented, while another power supply to the IO unit can be cut off, thereby saving the power consumption. In still another specific example, the state control signal may also include the state control signal configured to keep the analog circuit component in the first power domain 11 in the shutdown or standby state, to save the power consumption. In addition, the state control signal may further include the state control signal configured to keep the first power domain 11 in the normal working state, so that in a case that the first power domain 11 is powered up, the circuit component therein returns to the normal working state. It may be understood that, according to a specific requirement, another type of state control signal may alternatively be set, which is not limited herein.

In some embodiments, as shown in FIG. 1, the power domain management circuit 100 may further include a power-up identification unit 140. The power-up identification unit 140 may be configured to identify whether current power-up of the first power domain 11 is initial power-up or power-up after sleep, so as to generate a corresponding signal to control the operation of the SOC 10. Herein, the initial power-up may refer to a simultaneous power-up of the first power domain 11 and the second power domain 12, or the first power-up of the first power domain 11 after the second power domain 12 is powered up. While the power-up after sleep may refer to a non-first power-up of the first power domain 11 after the second power domain 12 is powered up. In a specific embodiment, the power-up identification unit 140 may include a latch. The latch may be configured to receive a power-up indication signal from the power supply 200, and to generate, according to the reset indication signal and the power-up indication signal, the power-up identification signal for identifying whether the current power-up of the first power domain 11 is the initial power-up or the power-up after sleep. In a specific example, as shown in FIG. 8, when the reset indication signal is valid at the high level, if the power-up indication signal is at the low level, it indicates the initial power-up, and if the power-up indication signal is at the high level, it indicates the power-up after sleep. At this time, the latch may latch the power-up indication signal at the high level, that is, the power-up identification signal is converted from the low level to the high level, so as to distinguish between the initial power-up and the power-up after sleep. In the SOC 10, another circuit component such as a register may control a corresponding working state based on whether it is the initial power-up according to the power-up identification signal in the latch, so as to avoid the interference brought by the subsequent change of the reset indication signal. In addition, after the power-up is reset, the level of the power-up indication signal from the power supply may vary freely, that is, may be used for implementing an input function. It should be noted that, in some other embodiments, another type of sequential logic circuit, such as a register and the like, may alternatively be used to implement the power-up identification unit, which is not limited herein.

In the technical solution of the present disclosure, the power domain management circuit for eliminating the signal isolation between the power domains based on the reset indication signal is provided. In addition, the power domain management circuit may further set up the isolation between the power domains based on the isolation set signal. In some embodiments, the power domain management circuit may be in a clock-free design. In this way, in a case that the power domains are isolated, there may not be any clocks or flip-flops brought by the clock in the power domain management circuit and the power-down domain of the system on chip, thereby helping to reduce the circuit complexity and the power consumption of the power domain management circuit and the system on chip including the same. In addition, in some embodiments, the working state of at least a portion of circuit components in the power-down domain in the power-down state may further be controlled as required. In addition, by setting the power-up identification unit, whether the current power-up of the power-down domain is the initial power-up or the power-up after sleep may be determined, so as to control the operation of a corresponding circuit component, such as a register and the like, according to a specific requirement, thereby further improving the flexibility and richness of the power domain management.

The words “left”, “right”, “front”, “rear”, “top”, “bottom”, “above”, “below”, “high”, “low” and the like in the specification and the claims, if present, are used for a descriptive purpose and are not necessarily used for describing the unchanged relative position. It is to be understood that the terms used in such a way are interchangeable in proper circumstances so that embodiments of the present disclosure described herein can, for example, operate in other orientations different from those shown herein or otherwise described. For example, when an apparatus in the accompanying drawings is reversed, a feature originally described as being “above” another feature may be described as being “below” the other feature in this case. The apparatus may alternatively be oriented in another manner (rotated by 90 degrees or in another orientation), and in this case, a relative spatial relationship is explained accordingly.

In the specification and the claims, when an element is referred to as being “on”, “attached to”, “connected to”, “coupled to”, or “in contact with” another element, or the like, the element may be directly on, directly attached to, directly connected to, directly coupled to, or directly in contact with the other element, or there may be one or more intervening elements. In contrast, when an element is referred to as being “directly on”, “directly attached to”, “directly connected to”, “directly coupled to”, or “directly in contact with” another element, there are no intervening elements. In the specification and the claims, that a feature is “adjacent to” another feature may mean that the feature has a portion that overlaps with the adjacent feature or a portion that is located above or below the adjacent feature.

As used herein, the word “exemplary” means “serving as an example, instance, or illustration” rather than as a “model” to be exactly reproduced. Any implementation exemplarily described herein is not necessarily to be explained as preferred or advantageous over other implementations. In addition, the present disclosure is not limited by any stated or implied theory provided in the technical field, background, summary or detailed description.

As used herein, the word “substantially” means that any minor variation caused by the deflect of the design or manufacture, the tolerance of the device or the element, the environmental influence, and/or any other factor is included. The word “substantially” also allows for the difference from the perfect or ideal situation caused by the parasitic effect, noise, and other practical considerations that may exist in the actual implementation.

Furthermore, terms like “first” and “second” and so on may also be used herein for a reference purpose only, and thus are not intended for a limitation. For example, the words “first”, “second” and other such numerical words relating to the structure or element do not imply the sequence or the order unless the context clearly indicates otherwise.

It should be further understood that the word “include/include”, when used herein, specifies the presence of stated features, integers, steps, operations, units, and/or components, but do not preclude the presence or addition of one or more other features, integers, steps, operations, units, and/or components, and/or combinations thereof.

In addition, when used in the present disclosure, the words “herein”, “foregoing”, “following”, “below”, “above” and words with similar meanings shall refer to the whole of the present disclosure rather than any particular part of the present disclosure. In addition, unless explicitly stated otherwise or understood in another manner in the context used, conditional language used in this specification, such as “can”, “may”, “for example”, “such as”, and the like, is generally intended to express that some embodiments include, while other embodiments do not include, some features, elements, and/or states. Therefore, such conditional language is generally not intended to imply that features, elements and/or states are required in one or more embodiments in any manner, whether these features, elements and/or states are included in one or more embodiments, or these features, elements and/or states are performed in any specific embodiment.

In the present disclosure, the term “provide” is used broadly for covering all manners of obtaining the object, therefore “provide some object” includes, but not limited to, “purchase”, “prepare/manufacture”, “arrange/set”, “install/assemble”, and/or “order” object. In addition, in the present disclosure, the terms “circuit”, “unit”, and “module” may be used interchangeably. As used herein, the term “and/or” includes any and all combinations of one or more of the associated listed items. The terms used herein are for the purpose of describing specific embodiments only and are not intended to limit the present disclosure. As used herein, the singular forms of “a”, “an” and “the” are intended to include the plural forms as well, unless clearly indicated otherwise in the context.

A person skilled in the art should be aware that the boundaries between the foregoing operations is merely illustrative. A plurality of operations can be combined into a single operation, and a single operation can be distributed in an additional operation, and the operations can be performed at least partially overlapping in time. Moreover, alternative embodiments may include a plurality of examples of particular operations, and the operation sequence may be changed in other various embodiments. However, other modifications, changes, and replacements are also possible. The aspects and elements of all the embodiments disclosed above may be combined in any manner and/or with aspects or elements of other embodiments, to provide a plurality of additional embodiments. Therefore, the specification and accompanying drawings are to be regarded as illustrative rather than restrictive. In fact, the novel apparatuses, method, and system described herein may be embodied in various other forms. In addition, various omissions, replacements, and changes can be made to the form of the method and system described herein without departing from the spirit of the present disclosure. For example, although blocks are presented in a given arrangement, an alternative embodiment may perform a similar function with a different component and/or circuit topology, and may delete, move, add, subdivide, combine, and/or modify some blocks. Each of these blocks may be implemented in various different manners.

The embodiments of the present disclosure may be described in a progressive manner, for same or similar parts in the embodiments, refer to such embodiments, and descriptions of each embodiment focus on a difference from other embodiments. In the present disclosure, the description of the reference terms “an embodiment”, “some embodiments”, “an example”, “a specific example”, “some examples”, or the like means that specific features, structures, materials or characteristics described in combination with the embodiment(s) or example(s) are included in at least one embodiment or example of the present disclosure. In the present disclosure, the schematic descriptions of the foregoing terms are not necessarily directed at the same embodiment or example. Besides, the specific features, the structures, the materials or the characteristics that are described may be combined in proper manners in any one or more embodiments or examples.

Although some specific embodiments of the present disclosure have been described in detail through examples, a person skilled in the art may understand that the foregoing examples are only for description, but not for limiting the scope of the present disclosure. Each embodiment disclosed herein may be randomly combined without departing from the spirit and scope of the present disclosure. It may also be understood by a person skilled in the art that various modifications may be made to the embodiments without departing from the scope and spirit of the present disclosure. The scope of the present disclosure is defined by the appended claims.

1. A power domain management circuit, comprising:
an enable unit, configured to generate an enable signal with a first preset level in a case of receiving an isolation set signal, or to generate an enable signal with a second preset level in a case of receiving a reset indication signal, wherein the second preset level is different from the first preset level; and
a clamping unit, electrically connected to the enable unit, and configured to clamp an initial signal transmitted from a first power domain to a second power domain to generate a target signal with a third preset level in a case of receiving the enable signal with the first preset level, or to skip clamping the initial signal to generate a target signal with a level that varies with a level of the initial signal in a case of receiving the enable signal with the second preset level, wherein the third preset level is same as or different from the first preset level.

2. The power domain management circuit according to claim 1, wherein the isolation set signal is configured to be generated before the first power domain is powered down relative to the second power domain; or
the reset indication signal is configured to be generated after the first power domain is powered up relative to the second power domain and is in a stable power-up state.

3. The power domain management circuit according to claim 1, wherein the reset indication signal is configured to reset at least a portion of circuit components in the first power domain after the first power domain is powered up relative to the second power domain.

4. The power domain management circuit according to claim 1, wherein the enable unit comprises a first register.

5. The power domain management circuit according to claim 4, wherein a reset trigger terminal of the first register is configured to receive the reset indication signal, and an output terminal of the first register is configured to output the enable signal.

6. The power domain management circuit according to claim 4, wherein the clamping unit comprises a first clamping unit, the initial signal comprises a clock signal; and
a first input terminal of the first clamping unit is configured to receive the enable signal, a second input terminal of the first clamping unit is configured to receive the clock signal, and an output terminal of the first clamping unit is electrically connected to a clock trigger terminal of the first register.

7. The power domain management circuit according to claim 4, wherein the clamping unit comprises a second clamping unit, the initial signal comprises an isolation setup signal, the target signal comprises the isolation set signal generated according to the enable signal and the isolation setup signal; and
a first input terminal of the second clamping unit is configured to receive the enable signal, a second input terminal of the second clamping unit is configured to receive the isolation setup signal, and an output terminal of the second clamping unit is electrically connected to an input terminal of the first register to transmit the isolation set signal to the first register.

8. The power domain management circuit according to claim 1, further comprising:
a state control unit, electrically connected to the enable unit, and configured to generate, according to the enable signal, a state control signal to be transmitted to the first power domain.

9. The power domain management circuit according to claim 8, wherein the state control unit comprises a first multiplexer, a selection control terminal of the first multiplexer is electrically connected to an output terminal of the enable unit, each of a plurality of input terminals of the first multiplexer is respectively configured to receive a corresponding state control signal, and an output terminal of the first multiplexer is configured to output a state control signal selected according to the enable signal.

10. The power domain management circuit according to claim 8, wherein the state control unit comprises a second register, the clamping unit comprises a first clamping unit and a third clamping unit, the initial signal comprises an input control signal, and the target signal comprises a state indication signal generated according to the enable signal and the input control signal;
a reset trigger terminal of the second register is configured to receive the reset indication signal;
a first input terminal of the first clamping unit is configured to receive the enable signal, a second input terminal of the first clamping unit is configured to receive a clock signal, and an output terminal of the first clamping unit is electrically connected to a clock trigger terminal of the second register; or
a first input terminal of the third clamping unit is configured to receive the enable signal, a second input terminal of the third clamping unit is configured to receive the input control signal, and an output terminal of the third clamping unit is electrically connected to an input terminal of the second register to transmit the state indication signal to the second register.

11. The power domain management circuit according to claim 10, wherein the second register is configured to generate a state control signal corresponding to the input control signal in a case of receiving the state indication signal, or to generate a state control signal corresponding to a normal working state in a case of receiving the reset indication signal.

12. The power domain management circuit according to claim 10, wherein the state control unit further comprises a delay module, an output terminal of the second register is electrically connected to an input terminal of the delay module, and the delay module is configured to delay the state indication signal.

13. The power domain management circuit according to claim 12, wherein the delay module comprises a second multiplexer, a selection control terminal of the second multiplexer is electrically connected to an output terminal of the enable unit, one input terminal of the second multiplexer is electrically connected to an output terminal of the second register, and an output terminal of the second multiplexer is configured to output a state control signal selected according to the enable signal.

14. The power domain management circuit according to claim 13, wherein another input terminal of the second multiplexer is configured to receive a state control signal corresponding to a normal working state.

15. The power domain management circuit according to claim 8, wherein the state control signal comprises at least one of:
the state control signal, configured to maintain power supply to a storage array of a static random access memory in the first power domain;
the state control signal, configured to maintain power supply to an input/output of an input/output unit in the first power domain;
the state control signal, configured to keep an analog circuit component in the first power domain in a shutdown state or a standby state; or
the state control signal, configured to keep the first power domain in a normal working state.

16. The power domain management circuit according to claim 1, further comprising:
a power-up identification unit, configured to identify whether current power-up of the first power domain is initial power-up or power-up after sleep.

17. The power domain management circuit according to claim 16, wherein the power-up identification unit comprises a latch, and the latch is configured to receive a power-up indication signal from a power supply, and to generate, according to the reset indication signal
